(19) United States
(12) Patent Application Publication
(10) Pub. No.: US 2015/0004318 A1
(43) Pub. Date: Jan. 1, 2015

(54) NOZZLE AND NOZZLE HEAD

(71) Applicant: BENEQ OY, Espoo (FI)

(72) Inventors: Tapani Alasaarela, Helsinki (FI); Pekka Soininen, Helsinki (FI); Mika Jauhiainen, Jyvaskyla (FI)

(21) Appl. No.: 14/371,906

(22) PCT Filed: Feb. 12, 2013
(86) PCT No.: PCT/FI2013/050154

§ 371 Date: Jul. 11, 2014

(30) Foreign Application Priority Data
Feb. 17, 2012 (FI) 20125186

(51) Int. Cl. C23C 16/455; C23C 16/44

(52) U.S. Cl. CPC C23C 16/45574; C23C 16/4412
USPC 427/255.28; 239/548

(57) ABSTRACT

A nozzle and nozzle head arranged to subject a surface of a substrate to gaseous precursors. The nozzle includes an output face via which the precursor is supplied, a longitudinal precursor supply element for supplying precursor and a longitudinal discharge channel open to and along the output face for discharging at least a fraction of the precursor supplied from the precursor channel. The precursor supply element is arranged to extend inside the discharge channel such that the precursor supply element divides the discharge channel in the longitudinal direction to a first discharge sub-channel and a second discharge sub-channel on opposite sides of the precursor supply element for supplying precursor through the discharge channel.

### FIELD OF THE INVENTION

The present invention relates to a nozzle for subjecting a surface of a substrate to a gaseous precursor and particularly to a nozzle head according to the preamble of claim 1. The present invention further relates to a nozzle head for subjecting a surface of a substrate to successive surface reactions of at least a first precursor and a second precursor, and particularly to a nozzle head according to the preamble of claim 16.

### BACKGROUND OF THE INVENTION

In the prior art several types of apparatuses, nozzle heads and nozzles are used for subjecting a surface of a substrate to successive surface reactions of at least a first precursor and a second precursor according to the principles of atomic layer deposition method (ALD). In ALD applications, typically two gaseous precursors are introduced into the ALD reactor in separate stages. The gaseous precursors effectively react with the substrate surface, resulting in deposition of a growth layer. The precursor stages are typically followed or separated by an inert-gas purge stage that eliminates the excess precursor from the surface of the substrate prior to the separate introduction of the other precursor. Therefore an ALD process requires alternating in sequence the flux of precursors to the surface of the substrate. This repeated sequence of alternating surface reactions and purge stages between is a typical ALD deposition cycle.

The prior art apparatuses for continuously operating ALD usually comprise a nozzle head having precursor nozzles arranged successively adjacent to each other such that the surface of the substrate may be subjected successively to surface reaction of at least a first and second precursors. The nozzles provide one or more first precursor supply channels for supplying the first precursor and one or more second precursor supply channels for supplying the second precursor. A nozzle head is usually also provided with one or more purge gas channels and one or more discharge channels for discharging both precursors and purge gas. In one prior art nozzle head the channels are arranged in the following order: at least a first precursor nozzle, a first discharge channel, purge gas channel, a discharge channel, a second precursor nozzle, a discharge channel, a purge gas channel and a discharge channel, optionally repeated a plurality of times.

The problem with this prior art nozzle head is that it comprises several different nozzles and channels which makes the nozzle head complicated and rather large. When the surface of the substrate is processed the nozzles and the nozzle head are moved in relation to the substrate such that the nozzles and nozzle head scan over the surface of the substrate subjecting the substrate surface successively to the different precursors. In industrial applications it is advantageous to form as many ALD cycles as possible with one scan. The prior art nozzles and nozzle heads do not provide compact and effective constructions for industrial scale apparatuses.

### BRIEF DESCRIPTION OF THE INVENTION

The object of the present invention is to provide a nozzle and a nozzle head such that the above mentioned prior art problems are solved or at least alleviated. The objects of the present invention are achieved with a nozzle according to the characterizing part of claim 1, in which a precursor supply element is arranged to extend inside a discharge channel such that the precursor supply element divides the discharge channel in the longitudinal direction to a first discharge sub-channel and a second discharge sub-channel on opposite sides of the precursor supply element for supplying precursor through the discharge channel. The objects of the present invention are further achieved with a nozzle head according to the characterizing part of claim 16, in which at least one of first and second precursor supply channels is arranged to supply precursor through a discharge channel for dividing the discharge channel in the longitudinal direction to a first discharge sub-channel and a second discharge sub-channel on opposite sides of the precursor supply channel.

The preferred embodiments of the present invention are described in dependent claims.

The invention is based on the idea of supplying the gaseous precursor material through a discharge channel such that a discharge sub-channel is formed on opposite sides of the precursor supply. The present invention provides a nozzle comprising an output face via which the precursor is supplied, a precursor supply element for supplying precursor and a longitudinal discharge channel open to and along the output face for discharging at least a fraction of the precursor supplied from the precursor channel. According to the present invention the precursor supply element is arranged to extend inside the discharge channel such that the precursor supply element divides the discharge channel in the longitudinal direction to a first discharge sub-channel and a second discharge sub-channel on opposite sides of the precursor supply element for supplying precursor through the discharge channel. Therefore the present invention provides a nozzle in which the precursor supply channel is arranged inside a discharge channel and the precursor is supplied through the discharge channel. This nozzle arrangement may further be used in a nozzle head having an output face and comprising one or more first longitudinal precursor supply channels for subjecting the surface of the substrate to the first precursor via the output face, one or more second longitudinal precursor supply channels for subjecting the surface of the substrate to the second precursor via the output face, and one or more longitudinal discharge channels open to the output face for discharging at least a fraction of the first and second precursor supplied from the first and second precursor supply channels. In the nozzle head at least one of the first and second precursor supply channels is arranged to supply precursor through a discharge channel for dividing the discharge channel in the longitudinal direction to a first discharge sub-channel and a second discharge sub-channel on opposite sides of the precursor supply channel. Therefore at least one of the first and second precursor supply channels may be arranged inside a discharge channel for dividing the discharge channel in the longitudinal direction to a first discharge sub-channel and a second discharge sub-channel on opposite sides of the precursor supply channel.

An advantage of the nozzle and nozzle head of the present invention is a compact structure in which the discharge channel and the precursor supply channel are nested. This eliminates the need for separate discharge channels and precursor supply channels. Furthermore, a single discharge channel is arranged to form a discharge sub-channel on both sides of the precursor supply channel instead of two separate discharge channels. Therefore, the nozzle and nozzle head is simpler in structure and more compact. This means that a larger number of precursor supply channels may be formed on a certain surface area of the output face of the nozzle head and further growth layers may be produces on the substrate surface with one scan.

### BRIEF DESCRIPTION OF THE DRAWINGS

In the following the invention will be described in greater detail by means of preferred embodiments with reference to the attached drawings, in which

FIG. 1 shows a schematic view of a nozzle head according to the present invention;

FIG. 2 shows a schematic view of another nozzle head according to the present invention;

FIG. 3 shows a schematic view of one embodiment of a nozzle according to the present invention;

FIG. 4 shows a schematic view of a nozzle head comprising nozzles of FIG. 3 arranged next to each other;

FIG. 5 shows a schematic view of another embodiment of a nozzle according to the present invention;

FIG. 6 shows a schematic view of another nozzle head according to the present invention;

FIG. 7 shows a schematic view of still another nozzle head according to the present invention;

FIG. 8 shows a schematic view of still another embodiment of a nozzle according to the present invention; and

FIG. 9 shows a schematic view of yet another embodiment of a nozzle according to the present invention.

### DETAILED DESCRIPTION OF THE INVENTION

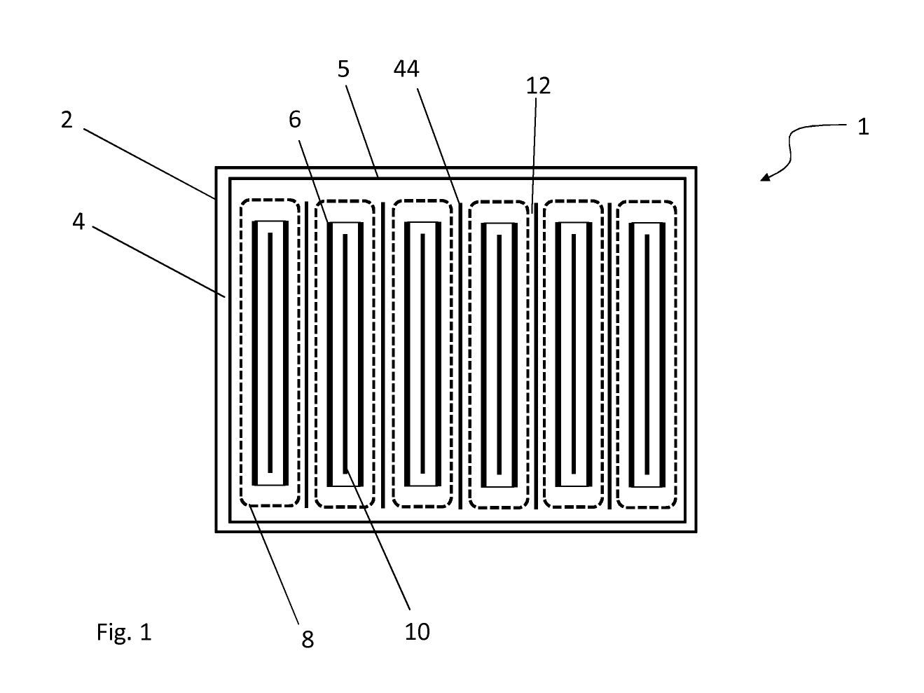

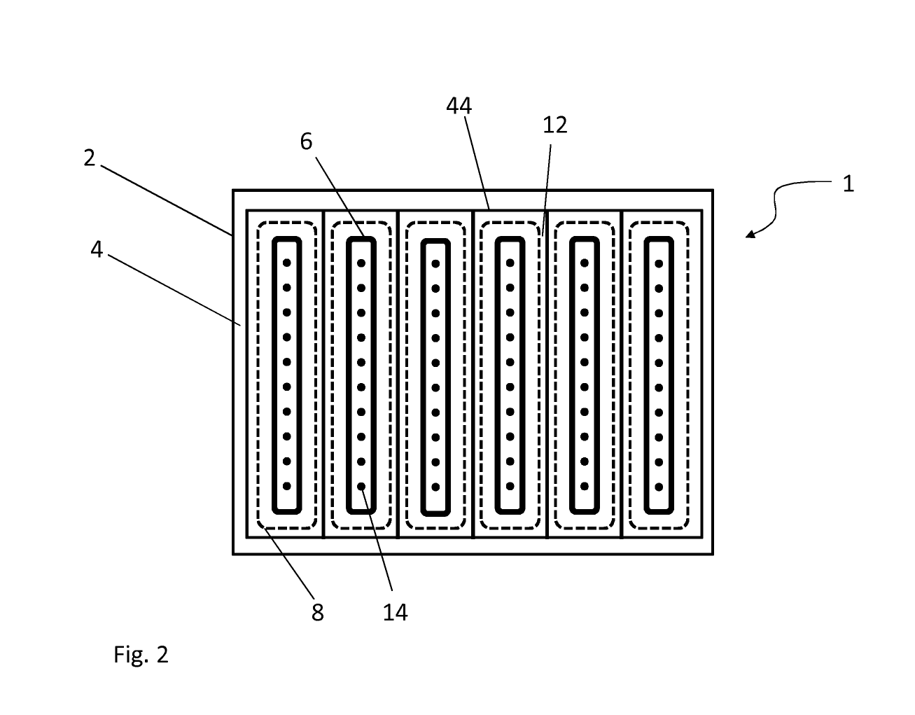

FIG. 1 shows schematically one embodiment of a nozzle head 1 according to the present. The nozzle head 1 comprises nozzle head body 2 and a nozzle head output face 4 via which the gaseous precursors are supplied. In the embodiment of FIG. 1 the nozzle head output face 4 is planar, but in an alternative embodiment it may also be non-planar, curved, cylindrical or have any other suitable form. The nozzle head 1 is provided with nozzles 8 arranged adjacently to each other and extending longitudinally along the output face 4. The nozzles 8 are shown with dashed lines in FIGS. 1 and 2. The nozzles 8 are separated with a distance or gap 12 from each other. The nozzles 8 comprise a discharge channel 6 and a precursor supply channel 10 arranged inside the discharge channel 6. In this embodiment the discharge channel 6 and the precursor supply channel 10 are formed as longitudinal channels. As shown in FIG. 1 the precursor supply channel 10 divides the discharge channel 6 into two discharge sub-channels in the longitudinal direction, one on each side of the precursor supply channel 10 for discharging at least a fraction of the supplied precursor. In a preferred embodiment the discharge channel 6 and the precursor supply channel 10 flush with the nozzle head output face 4. Alternatively the discharge channel 6 and/or the precursor supply channel may protrude from the nozzle head output face 4 or may be partly below the nozzle head output face 4. It should be noted that the nozzles 8 may be integral parts of the nozzle head 1 and the nozzle head body 2 or alternatively they may be detachable parts which may be removed or replaced. The gap 12 between the nozzles 8 is in this embodiment provided with a purge gas channel 44 for supplying purge gas, such as nitrogen. The purge gas channels are preferably longer than the nozzles 8 or the precursor supply channels. The purge gas channel 44 is provided for separating the adjacent nozzles 8 and the precursors from each other and for purging the surface of the substrate. The nozzle head output face 4 is further provided with discharge perimeter 5, which surrounds the nozzles 8 and the purge gas channels 44. The discharge perimeter 5 is connected to vacuum pump or the like such that it may discharge precursors and purge gas from the nozzle head output face 4. In this embodiment the discharge perimeter 5 is continuous, but alternative it may be formed from two or more separate discharge channels parts arranged to surround the nozzles 8 and the purge gas channels 44. It should be noted that a purge gas perimeter (not shown) may also be arranged to the nozzle in the same way as the discharge perimeter 5. The purge gas perimeter is preferably provided on inner side of the discharge perimeter 5 on the nozzle head output face 4.

FIG. 2 shows an alternative embodiment in which the precursor supply channel comprises several supply holes 14 extending and opening towards the nozzle head output face 4. The precursor supply channel 10 is furthermore arranged in the middle of the discharge channel 6 such that the discharge channel 6 surrounds the precursor supply channel 10 from all directions on the nozzle head output face 4. In other words the ends of the discharge channels 6 on the opposite sides of the precursor supply channel 6 are connected to form a discharge channel surrounding the precursor supply channel 10. Also in this embodiment the precursor supply channel divides the discharge channel 6 into two discharge sub-channels in the longitudinal direction, one on each side of the precursor supply channel. In addition, the ends of the discharge sub-channels connect to each other forming a circumferential discharge channel around the precursor supply channel on the nozzle head output face 4. In FIGS. 1 and 2 the gap 12 between the nozzles 8 may be provided with a purge gas channel for supplying purge gas, such as nitrogen for purging the substrate surface. In the embodiment of FIG. 2, the purge channels 44 are connected to each other such that the purge gas channels 44 surround separately each nozzle 8 and also all the nozzles 8 on the nozzle head output face 4. It should be noted that the purge gas channels 44 also be arranged to surround only each nozzle 8 separately or only all the nozzles 8. When the purge gas channels 44 are arranged to surround the nozzles 8 the surrounding discharge perimeter 5, shown in FIG. 1, may be omitted. However, the discharge perimeter 5 may also be provided on the nozzle head output face 4 surrounding the connected purge gas channels 44.

It should be noted that the same structural parts are denoted with same reference numerals in FIGS. 1 to 8.

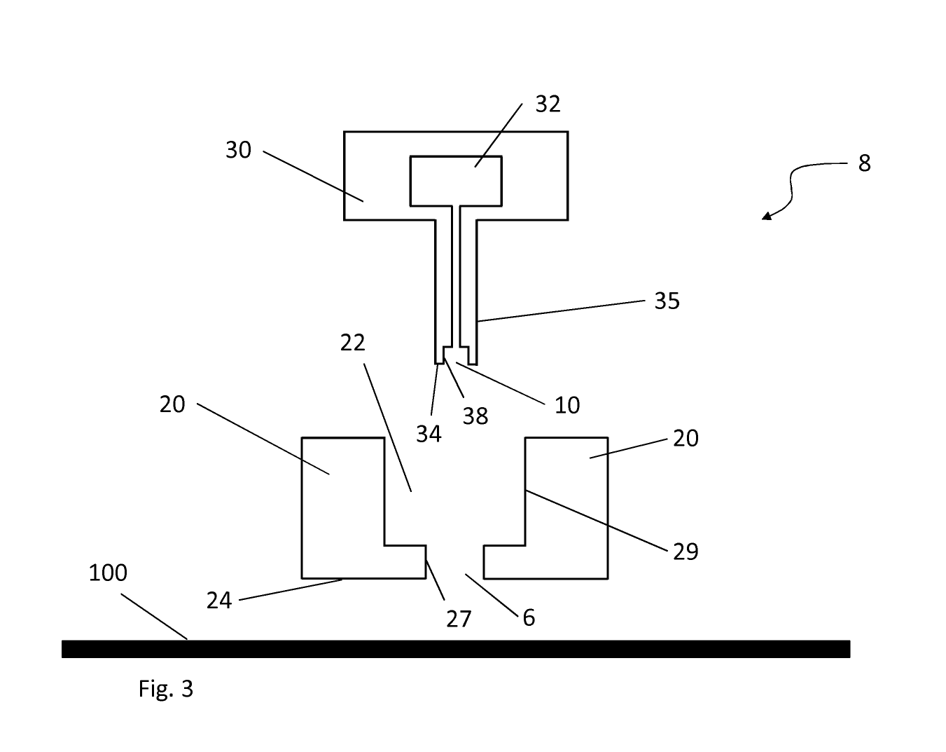

FIG. 3 shows one embodiment the nozzle 8 according to the present invention. The nozzle 8 comprises a nozzle body 20 and a precursor supply element 30 for supplying precursor on the surface of a substrate 100. In FIG. 3 the nozzle 8 is shown disassembled such that the precursor supply element 30 is out of the nozzle body 20. Thus in this embodiment the precursor supply element 30 and the nozzle body 20 are separate parts, but in alternative embodiment they may also be integral parts. Therefore, the precursor supply element 30 may be integral part of the body 20 or a separate part. The nozzle body 20 comprises a nozzle output face 24 via which the precursor is supplied. The nozzle body 20 further comprises a longitudinal discharge channel 6 open to and along the nozzle output face 24. The discharge channel 6 has side walls 27 extending the longitudinal direction of the discharge channel 6. The nozzle body 20 further comprises a discharge conduit 22 extending substantially parallel and in fluid connection with the discharge channel 6 for exhausting discharged material from the discharge channel 6. Accordingly the nozzle body 20 is arranged to form the discharge channel 6 and discharge conduit 22 having longitudinal walls 29. The width of the discharge conduit 22 is greater than the width of the discharge channel 22 for enhancing the discharge pressure. The discharge conduit 22 and the discharge channel 6 are connected to a suction device (not shown) for providing suction. In a preferred embodiment the suction may be arranged to one or both longitudinal ends or the discharge conduit 22 and/or discharge channel 6.

The precursor supply element 30 is arranged to be installed at least partly inside the nozzle body 20. The precursor supply element 30 comprises one or more longitudinal precursor supply channels 10 open to the nozzle output face 24 for supplying precursor via the output face 24. The precursor supply element 30 further comprises a precursor conduit 32 in fluid connection with the precursor supply channel 10 for conducting precursor to the precursor supply channel 10. In the embodiment of FIG. 3 the precursor supply channel 10 is formed as a longitudinal channel open to and along the output face 24 and extending a as channel from the precursor conduit 32 to the end face 34 of the precursor supply channel 10. The longitudinal precursor supply channel 10 comprises an expansion 38 in the vicinity of the output face 24 and the end face 34 for increasing the width of the longitudinal precursor channel 10 at the output face 24. The expansion spreads and uniforms the precursor supply to the substrate surface. The expansion 38 equalizes the precursor supply in the width direction of the precursor supply channel 10 and decelerates the supply rate of the precursors. The expansion 38 provides a pressure balancing structure when the nozzle 8 or the nozzle head 1 is arranged close to a substrate surface.

In an alternative embodiment the precursor supply element may comprise one or more one or more precursor supply holes 14 extending from the precursor conduit 32 and opening to the output face 24 for forming the precursor supply channel. These kinds of supply holes 14 may extend in a transversal direction in relation to the longitudinal direction of the discharge channel 6. The precursor supply holes 14 may form the supply channel or channels. Alternatively the precursor supply holes 14 extend between the precursor conduit 32 and the longitudinal precursor supply channel 10 open to and along the output face 24. In one embodiment the longitudinal expansion 38 may form the precursor supply channel 10 and the supply holes extend between the expansion 38 and the precursor conduit 32.

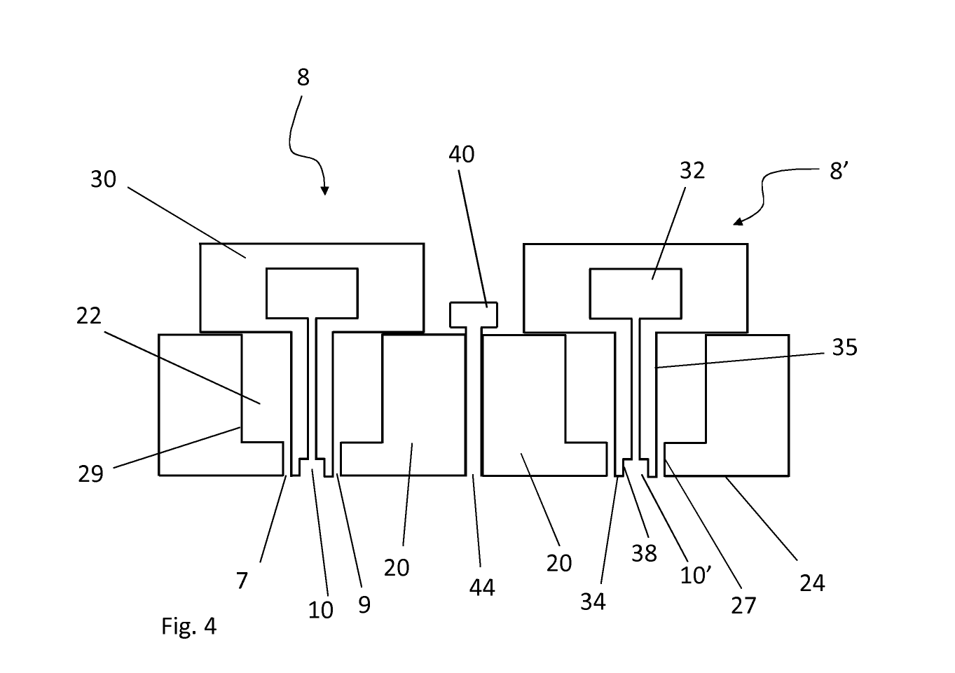

FIG. 4 shows two nozzles 8, 8′ of FIG. 3 are installed adjacently and assembled such that precursor supply element 30 is inside the nozzle body 20. The first nozzle 8 is arranged to supply a first precursor via the first precursor supply channel 10 and the second precursor 8′ is arranged to supply second precursor via the second precursor supply channel 10′. Between the nozzles 8, 8′ there is provided a purge gas element for supplying purge gas.

The purge gas element comprises a purge gas conduit 40 and a purge gas supply channel 44 open to the nozzle output face 24. A nozzle head of FIGS. 1 and 2 may be formed by arranging two or more nozzles 10, 10′ adjacently.

A shown in FIG. 4, the precursor supply element 30 is arranged to extend through the discharge channel 6 to the output face 24. Thus the precursor supply element 30 is arranged to extend longitudinally inside the discharge channel 6 such that the precursor supply element 30 divides the discharge channel 6 in the longitudinal direction to a first discharge sub-channel 7 and a second discharge sub-channel 9 on opposite sides of the precursor supply element 30 for supplying precursor through the discharge channel 6. This means that the precursor is supplied from the nozzle 8, 8′ through the discharge channel 6. In the embodiment of FIG. 4 the precursor supply element 30 is also arranged to extend through the discharge conduit 22 and the discharge channel 6 to the output face 24 such that the precursor channel 10 divides the discharge conduit 22 to two discharge sub-conduits on opposite sides of the precursor supply element 30. The precursor supply element 30 may be arranged to provide a fluid connection between the discharge subconduits of the discharge conduit 22. Alternatively there is no fluid connection between the discharge sub-conduits. The precursor supply element 30 is preferably arranged to extend inside the discharge channel 6 such that the end face 34 of the supply element 30 is substantially flush with the output face 24. The discharge sub-channels 7, 9 are thus formed between the outer wall 35 of the precursor supply channel 10 and the inner walls 27 of the discharge channel 6.

The nozzle 8, 8′ of FIG. 4 enables one discharge channel 6 to be used for providing two discharge channels 7, 9 on opposite sides of the precursor supply channel 10, 10′. This also enables to use one suction device or suction connection for these both discharge sub-channels 7, 9. The precursors may be supplied to the precursor conduits 32 from the longitudinal ends of the precursor conduits 32. Furthermore, the present invention enables different precursors to be supplied from different ends to the longitudinal precursor conduits 32.

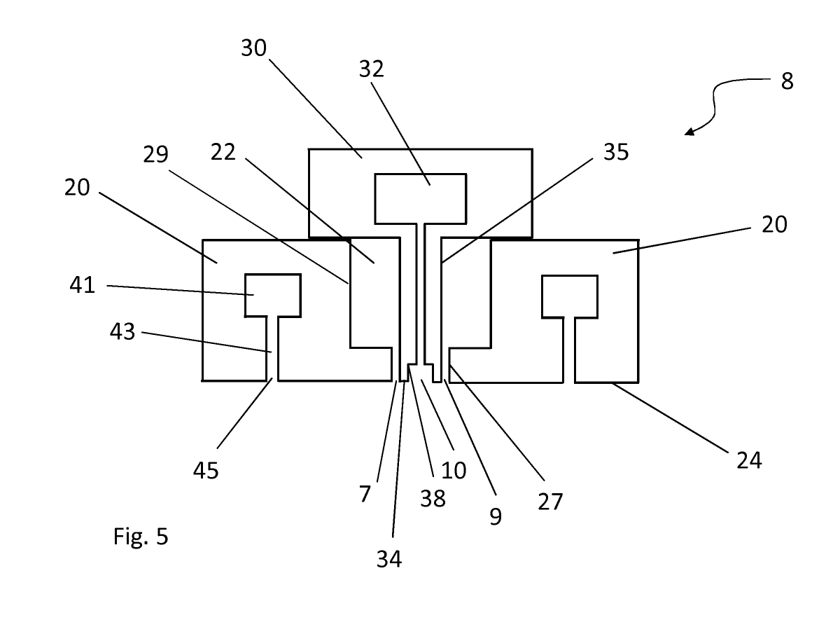

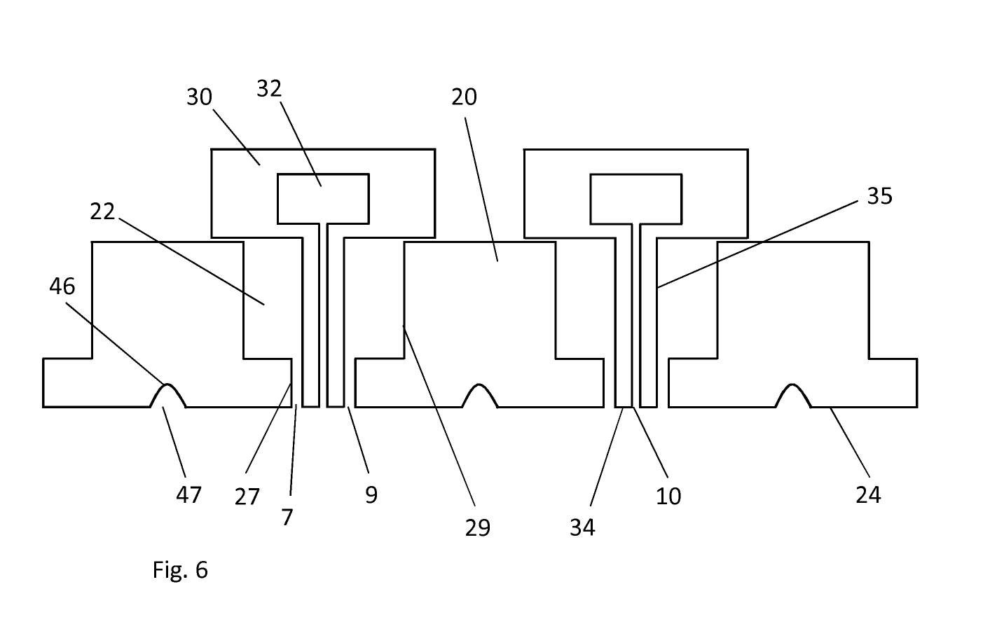

FIG. 5 shows an alternative embodiment in which the purge gas channels 45 is formed to the nozzle body 20. The nozzle body 20 therefore comprises a purge gas conduit 41 and a purge gas supply channel open to the nozzle output face 24 and extending longitudinally substantially in the direction of the discharge channel 6. This purge gas arrangement provides an integral purge gas supply to the nozzle 8. FIG. 6 shows an alternative embodiment in which a nozzle head is formed by arranging nozzles adjacent to each other. In this embodiment the nozzle body 20 comprises a purge gas channel 47 extending open to the nozzle output face 24 and extending longitudinally substantially in the direction of the discharge channel 6. In this embodiment one purge gas channel 47 is provided between two discharge channels 6 and between the discharge sub-channels 7 and 9. In this embodiment there is no expansion in the vicinity of the end face 34 of the precursor supply element 30. The nozzle head has a compact structure the nozzle body 20 or the nozzle head body 2 has only two different channels on the output face 4, 24, the purge gas channel 45, 47 and the discharge channel 6 as the precursor supply channel 10 is formed inside the discharge channel 6.

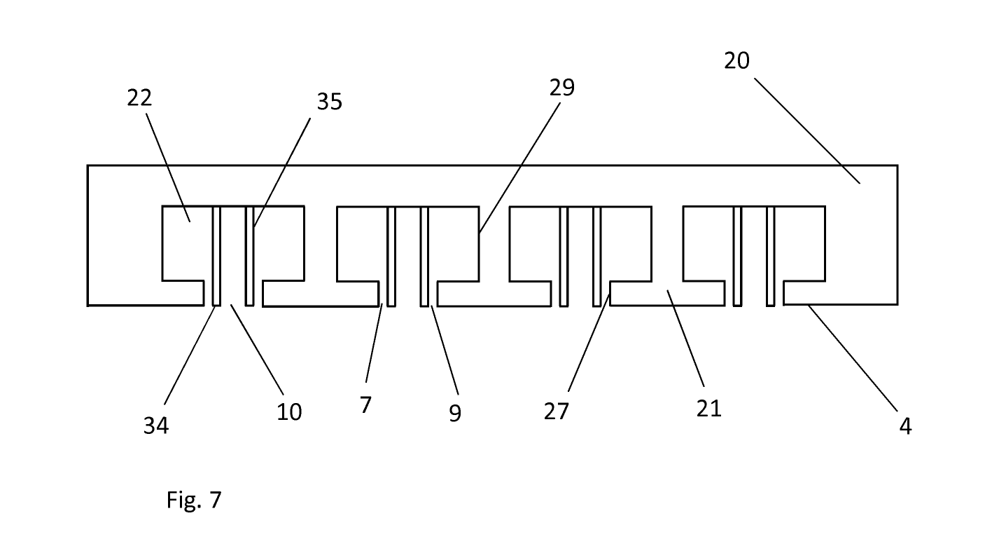

FIG. 7 shows a nozzle head in which the nozzle head body 2 comprises discharge conduits 22 in fluid connection to the discharge channels 6. There is also a precursor supply channels 10 extending through the discharge conduit 22 and the discharge channel 6 to the nozzle head output face 4. In this embodiment the longitudinal discharge channels 6, discharge conduits 22 and the precursor supply channels 10 are formed as integral parts or machined shapes to the nozzle head body 2. The discharge channels and the discharge conduits 22 are separated from each other with partitioning walls 21. It should be noted as there is no precursor conduit in the embodiment of FIG. 7, also the discharge conduit 22 may be omitted or the discharge channel 6 may have uniform width also in the height direction.

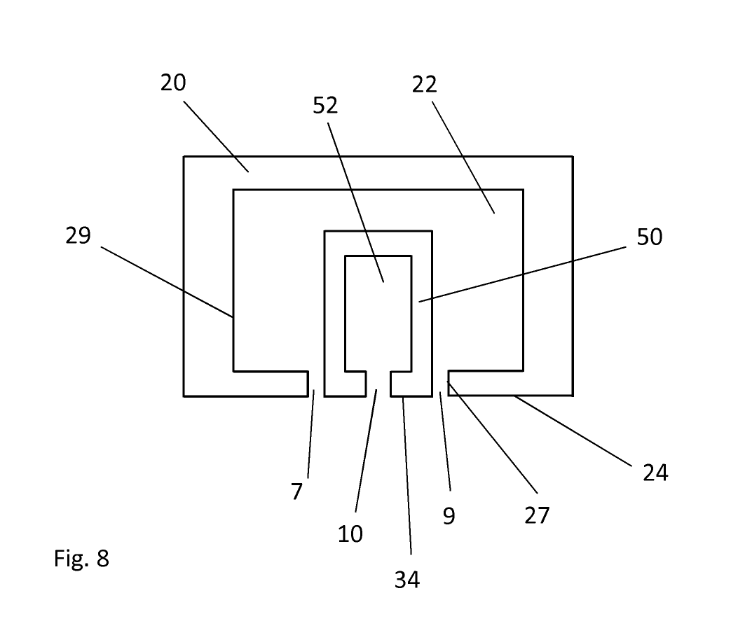

FIG. 8 shows an alternative embodiment of the nozzle in which the precursor supply element 50 extends inside the discharge conduit 22 or discharge channel but not through the discharge conduit 22 in the height or width direction. Thus the precursor supply element 50 may provide a fluid connection between the first and second discharge sub-channels 7, 9. The precursor supply element 50 extends substantially in a nested fashion inside the discharge conduit 22 or the discharge channel 6, at least in the lateral direction of the discharge channel 6. In one embodiment the precursor supply element 50 may also extend substantially coaxially inside the discharge conduit 22 or the discharge channel 6, at least in the lateral direction of the discharge channel 6. The precursor supply element 50 comprises a precursor conduit 52 and a precursor supply channel 10 opening on and along the nozzle output face 24 such that it divides the discharge channel 6 into two discharge sub-channels 7, 9. The precursor supply element 50 is arranged to extend inside the discharge channel 6 such that the end face 34 the supply element 50 is substantially flush with the nozzle output face 24.

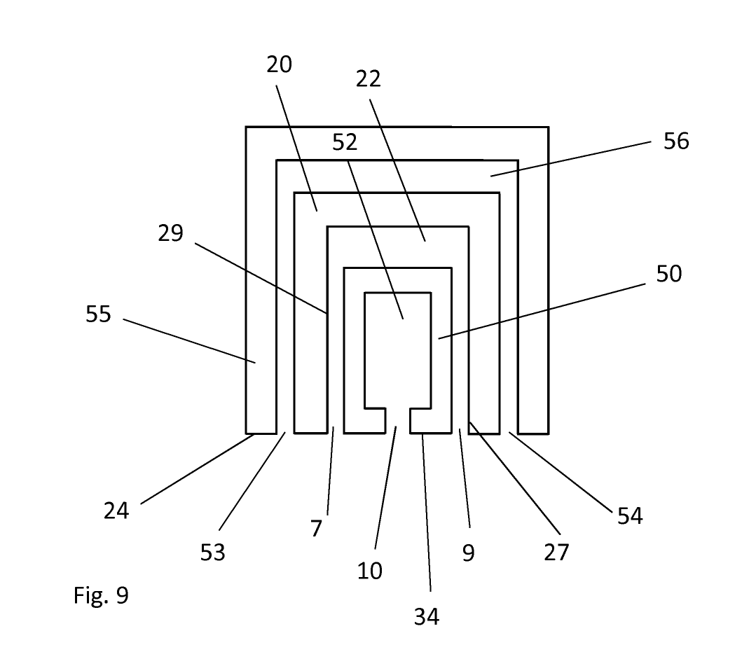

FIG. 9 shows an alternative embodiment in which both the precursor supply channel 10 and the discharge channels 7, 9 are arranged to extend longitudinally inside the purge gas element 55 such that they divide the purge gas channel in the longitudinal direction to a first purge sub-channel 53 and a second purge gas sub-channel 54 on opposite sides of the precursor supply element 50 and the discharge channels 7, 9. The purge gas element also comprises a purge gas conduit 56 for supplying purge gas to the purge gas sub-channels 53, 54. In this embodiment the precursor supply element 50 and the nozzle body 20 forming the discharge channels 7, 9 are nested inside the purge gas element 55 and purge gas conduit 56. Thus there is fluid connection between the purge gas sub-channels 53, 54 via the purge gas conduit 56. The discharge conduit 22 may extends substantially in a nested fashion inside purge gas element 55. In one embodiment the discharge conduit 22 may also extend substantially coaxially inside the purge gas conduit 56, at least in the lateral direction of the discharge channels 7, 9. It should be noted the principle shown in FIG. 9 may also be applied to the nozzles and nozzle heads of figure 1 to 8. In other words the precursor supply channel and the discharge channel may be arranged inside the purge gas channel such that the precursor supply channel and the discharge channel divide the purge gas channel into first and second purge gas sub-channels 53, 54 on opposite side of the discharge channel and precursor supply channel. Therefore his principle may also be used in the nozzle structures shown in FIGS. 3 to 8.

The present invention therefore provides a nozzle head in which nozzle 8, 8′ described above may be used for subjecting a surface of a substrate to successive surface reactions of at least of first and second gaseous precursor for forming thin film on the surface of the substrate according to the principles of atomic layer deposition. 25. The nozzle described above may be used for subjecting a surface of a substrate to surface reaction a gaseous precursor.

The nozzle head of the present invention for subjecting a surface of a substrate 100 to successive surface reactions of at least a first gaseous precursor and a second gaseous precursor may comprise one or more first longitudinal precursor supply channels 10 for subjecting the surface of the substrate 100 to the first precursor via the nozzle head output face 4, one or more second longitudinal precursor supply channels 10′ for subjecting the surface of the substrate 100 to the second precursor via the output face 4, and one or more longitudinal discharge channels 6 open to the output face 4 for discharging at least a fraction of the first and second precursor supplied from the first and second precursor supply channels 10, 10′. According to the present invention at least one of the first and second precursor supply channels 10, 10′ is arranged to supply precursor through a discharge channel 6 for dividing the discharge channel 6 in the longitudinal direction to a first discharge sub-channel 7 and a second discharge sub-channel 9 on opposite sides of the precursor supply channel 10, 10′. In a preferred embodiment all the precursors are supplied through the discharge channels 6. Thus the first and second supply channels 10, 10′ may be each arranged to supply precursor through a discharge channel 6, or that the first and second supply channels 10, 10′ may be each arranged inside a discharge channel 6. Alternatively it is also possible that only one precursor channels is arranged according to the present invention.

Accordingly at least one of the first and second precursor supply channels 10, 10′ of the nozzle head is arranged inside a discharge channel 6 for dividing the discharge channel 6 in the longitudinal direction to a first discharge sub-channel 7 and a second discharge sub-channel 9 on opposite sides of the precursor supply channel 10, 10′. This means that the first and second precursor supply channels 10, 10′ may be arranged to extend through the discharge channel 6 to the nozzle head output face 4 in a direction transversal to the longitudinal direction of the discharge channel 6. The first and second precursor supply channels 10, 10′ are arranged to extend inside and along the discharge channel 6. They may also be arranged to extend substantially coaxially inside and along the discharge channel 6, at least in the width direction of the discharge channel 6.

It will be obvious to a person skilled in the art that, as the technology advances, the inventive concept can be implemented in various ways. The invention and its embodiments are not limited to the examples described above but may vary within the scope of the claims.

1-27. (canceled)

28. A nozzle arranged to subject a surface of a substrate to a gaseous precursor, the nozzle comprising:
an output face via which the precursor is supplied;
a precursor supply element for supplying precursor;
a longitudinal discharge channel open to and along the output face for discharging at least a fraction of the precursor supplied from the precursor supply element, and
a body that forms the discharge channel, and the body further comprises a discharge conduit extending substantially parallel and in fluid connection with the discharge channel for exhausting discharged precursor from the discharge channel, that the precursor supply element is arranged to extend longitudinally inside the discharge channel such that the precursor supply element divides the discharge channel in the longitudinal direction to a first discharge sub-channel and a second discharge sub-channel on opposite sides of the precursor supply element for supplying precursor through the discharge channel, and the precursor supply element is also arranged to extend through the discharge conduit such that the precursor supply element divides the discharge conduit into two discharge sub-channels on opposite sides of the precursor supply element.

29. A nozzle according to claim 28, wherein the precursor supply element is an integral part of the body or a separate part.

30. A nozzle according to claim 28, wherein the precursor supply element comprises:
one or more precursor supply channels open to the output face for supplying precursor via the output face; and/or
a precursor conduit in fluid connection with the precursor supply channel for conducting precursor to the precursor supply channel; and/or
an expansion in the vicinity of the output face for increasing the width of the precursor channel at the output face; and/or
one or more precursor supply holes extending from the precursor conduit and opening to the output face for forming the precursor supply channel; and/or
one or more precursor supply holes extending from the precursor conduit and opening to the output face for forming the precursor supply channel, the precursor supply holes forming the supply channels, or the precursor supply holes extending between the precursor conduit and the precursor supply channel open to and along the output face.

31. A nozzle according to claim 28, wherein:
the precursor supply element extends through the discharge channel to the output face; or
the precursor supply element extends through the discharge conduit and the discharge channel to the output face such that the precursor supply element divides the discharge conduit into two discharge sub-conduits on opposite sides of the precursor supply element.

32. A nozzle according to claim 28, wherein:
the precursor supply element extends inside the discharge conduit and provides a fluid connection between the first and second discharge sub-channels; and/or
the precursor supply element is arranged to extend inside the discharge channel such that the end face of the precursor supply element is substantially flush with the output face.

33. A nozzle according to claim 30, wherein the nozzle further comprises at least one purge gas channel open to the output face.

34. A nozzle according to claim 33, wherein the precursor supply channel and the discharge channel are arranged inside the purge gas channel such that the precursor supply channel and the discharge channel divide the purge gas channel into first and second purge gas sub-channels on opposite side of the discharge channel and precursor supply channel.

35. A nozzle head for subjecting a surface of a substrate to successive surface reactions of at least a first gaseous precursor and a second gaseous precursor, the nozzle head having an output face and comprising:
one or more first longitudinal precursor supply channels for subjecting the surface of the substrate to the first precursor via the output face; and
one or more second longitudinal precursor supply channels for subjecting the surface of the substrate to the second precursor via the output face, and
one or more longitudinal discharge channels open to the output face for discharging at least a fraction of the first and second precursor supplied from the first and second precursor supply channels,
a discharge conduit extending substantially parallel and in fluid connection with the discharge channel for exhausting discharged precursor from the discharge channel, and at least one of the first and second precursor supply channels is arranged to supply precursor through the discharge conduit and the discharge channel, the at least one first and second precursor supply channels dividing the discharge conduit in the longitudinal direction on opposite sides of the precursor supply channel and the discharge channel in the longitudinal direction to a first discharge sub-channel and a second discharge sub-channel.

36. A nozzle head according to claim 35, wherein:
the first and second supply channels are each arranged to supply precursor through a discharge channel, or that the first and second supply channels are each arranged inside a discharge channel.

37. A nozzle head according to claim 35, wherein:
the first and second precursor supply channels are arranged to extend through the discharge channel to the output face in a direction transversal to the longitudinal direction of the discharge channel; or
the first and second precursor supply channels are arranged to extend inside and along the discharge channel; or
the first and second precursor supply channels are arranged to extend substantially coaxially inside and along the discharge channel.

38. A nozzle head according to claim 35, wherein:
the nozzle head further comprises one or more purge gas channels for supplying purge gas to the surface of the substrate; or
the nozzle head further comprises one or more purge gas channels provided between the discharge channels for supplying purge gas to the surface of the substrate.

39. A nozzle head according to claim 35, wherein the nozzle head further comprises discharge perimeter surrounding the nozzles on the output face.

40. A method comprising subjecting the surface of the substrate to surface reaction of the gaseous precursor with the nozzle of claim 28.

41. A method comprising subjecting the surface of the substrate to successive surface reactions of at least the first and second gaseous precursors with the nozzle head of claim 35, and forming a thin film on the surface of the substrate by atomic layer deposition.
